(19) United States
(12) Patent Application Publication
(10) Pub. No.: US 2010/0120178 A1
(43) Pub. Date: May 13, 2010

(54) Process Control Methods and Systems

(76) Inventors: Seok-Hyun Lim, Seoul (KR); Myeong-Cheol Kim, Suwon-si (KR); Yong-Jin Kim, Suwon-si (KR); Moon-Sang Lee, Hwaseong-si (KR); Ki-Chul Hwang, Suwon-si (KR)

Correspondence Address: F. CHAU & ASSOCIATES, LLC, 130 WOODBURY ROAD, WOODBURY, NY, 11797, US

(21) Appl. No.: 12/616,510

(22) Filed: Nov. 11, 2009

(30) Foreign Application Priority Data
Nov. 11, 2008 (KR) 10-2008-0111798

(51) Int. Cl. H01L 21/66

(52) U.S. Cl. 438/16; 257/E21.53

(57) ABSTRACT

A process control method includes setting first through fourth conditions, forming a first pattern by performing a first process on a semiconductor wafer, measuring the first pattern using a first measuring equipment to obtain a first result, comparing the first result with the first condition, forming a second pattern by performing a second process on the semiconductor wafer, comparing a period of the second process with the second condition, measuring the second pattern using a second measuring equipment to obtain a second result, comparing the second result with the third condition, forming a third pattern by performing a third process on the semiconductor wafer, measuring the third pattern using the a second measuring equipment to obtain a third result, and comparing the third result with the fourth condition.

### PRIORITY STATEMENT

This application claims the benefit of priority under 35 U.S.C. §119 from Korean Patent Application No. 10-2008-0111798, filed on Nov. 11, 2008, the contents of which are herein incorporated by reference in their entirety.

### BACKGROUND

1. Field

The present disclosure is directed to process control methods and systems for fabricating semiconductor devices.

2. Description of Related Art

Semiconductor devices are becoming ever more highly integrated and miniaturized. With the miniaturization of the semiconductor devices come processes to control fabrication based on measurement. Technologies that have been developed to overcome the resolution limitations of photolithography include immersion lithography, double exposure technology, double patterning technology, double etching technology, etc. These technologies provide improved capabilities for forming fine patterns, and will be applied more frequently in the future.

### SUMMARY

Exemplary embodiments provide process control methods capable of effectively controlling processes of fabricating semiconductor devices by making the most of measuring capability of measuring equipment.

Exemplary embodiments also provide process control systems capable of effectively controlling processes of fabricating semiconductor devices by making the most of measuring capability of measuring equipment.

Exemplary embodiments are directed to process control methods. One of the process control methods includes: setting first through fourth conditions, forming a first pattern by performing a first process on a semiconductor wafer, measuring the first pattern using a first measuring equipment, comparing a first result of measuring the first pattern using the first measuring equipment with the first condition, forming a second pattern by performing a second process on the semiconductor wafer, comparing a period of the second process with the second condition, measuring the second pattern using a second measuring equipment, comparing a second result of measuring the second pattern using the second measuring equipment with the third condition, forming a third pattern performing a third process on the semiconductor wafer, measuring the third pattern using the a second measuring equipment, and comparing a third result of measuring the third pattern using the second measuring equipment with the fourth condition.

In exemplary embodiments, the first condition may include information about formation of the first pattern associated with a thickness of the first pattern.

In exemplary embodiments, the second condition may include a maximum value of the number of times which the second process is preformed.

In exemplary embodiments, the third condition may include information about formation of the second pattern associated with a line width of the second pattern, and the fourth condition may include information about formation of the third pattern associated with a line width of the third pattern.

In exemplary embodiments, the first pattern may include a pattern of a material layer may be formed on the entire surface of the semiconductor wafer, and the second pattern may include a mask pattern formed on the material layer. Further, the third pattern may include a pattern of the material layer patterned using the mask pattern as a patterning mask.

In exemplary embodiments, the first process may be a process of forming a material layer on the entire surface of the semiconductor wafer, and the second process may be a process of forming a photoresist pattern on the material layer. Further, the third process may be a process of patterning the material layer using the photoresist pattern as a patterning mask.

In exemplary embodiments, measuring the first pattern using the first measuring equipment may include measuring a characteristic of the first pattern corresponding to the first condition.

In exemplary embodiments, measuring the second pattern using the second measuring equipment may include measuring a characteristic of the second pattern corresponding to the third condition.

In exemplary embodiments, the process control method may further include measuring the second pattern using third measuring equipment after comparing the result of measuring the second pattern using the second measuring equipment with the third condition. Further, the process control method may further include correcting a result of measuring the second pattern using the second measuring equipment in consideration of a measurement error of the third measuring equipment, or comparing a result of measuring the second pattern using the third measuring equipment with the result of measuring the second pattern using the second measuring equipment. Otherwise, the process control methods include correcting the first conditions and/or the recipes according to a result of the comparison.

In exemplary embodiments, measuring the third pattern using the second measuring equipment may include measuring a characteristic of the third pattern corresponding to the fourth condition.

In exemplary embodiments, the process control method may further include measuring the third pattern using third measuring equipment after comparing the result of measuring the third pattern using the second measuring equipment with the fourth condition. Further, the process control system may further include correcting the result of measuring the third pattern using the second measuring equipment in consideration of a measurement error of the second measuring equipment, or comparing the result of measuring the third pattern using the third measuring equipment with the result of measuring the third pattern using the second measuring equipment. Otherwise, the process control methods include correcting the first conditions and/or the recipes according to a result of the comparison.

In exemplary embodiments, the first process may be performed in first process equipment, the second process may be performed in second process equipment, and the third process may be performed in third process equipment. Here, the first, second and third process equipments may be different from each other. Further, the second measuring equipment may be included in the third process equipment.

Another process control method includes: setting first, second, third, and fourth conditions, wherein the first condition includes thickness information, the second condition includes a period information, the third condition includes size information, and the fourth condition includes size information, forming a material layer by performing a deposition process on a semiconductor wafer, measuring thickness of the material layer using a first optical measuring equipment to obtain a first result including thickness information of the material layer, comparing said first result with the first condition, forming a mask pattern by performing a photolithography process on the semiconductor wafer, comparing a period of the photolithography process with the second condition, measuring the mask pattern using a second optical measuring equipment to obtain a second result including sizes information of the mask pattern, comparing said second result with the third condition, forming a third pattern performing a patterning process, the patterning process patterning the material layer using the mask pattern as a patterning mask, measuring the third pattern using the second optic measuring equipment to obtain a third result, and comparing the third result with the fourth condition, when the period of the photolithography process does not satisfy the second condition, measuring the mask pattern using an electron beam measuring equipment to obtain a fourth result and comparing the fourth result with the second result, and correcting the third condition based on the fourth result, and when the third result does not satisfy the fourth condition, measuring the third pattern using the electron beam measuring equipment to obtain a fifth result, and correcting the fourth condition based on the fifth result.

Other exemplary embodiments are directed to process control systems. One of the process control systems includes, a main cluster including a logic unit to set process conditions and a storage unit to store measured data; a first cluster including a first process equipment and a first optical measuring equipment; a second cluster including a second process equipment; a third cluster including a third process equipment and a second optical measuring equipment; and a scanning electron microscope, wherein the main cluster provides the process conditions to the first cluster, the second cluster, and the third cluster by signal buses, wherein the main cluster is provided the measured data from the first optical measuring equipment, the second optical measuring equipment, and the scanning electron microscope.

In other exemplary embodiments, the main cluster further includes a comparing unit to compare the process conditions with the measured data.

In other exemplary embodiments, the first process equipment is deposition equipment, the second process equipment is photolithography equipment, and the third process equipment is etching process equipment.

Another exemplary embodiment is directed to a process control system. One of the process control systems includes a main controller including a logic unit to set process conditions, a storage unit to store measured data, and a comparing unit to compare the process conditions with the measured data; a first process equipment including a first optical measuring equipment therein; a second process equipment; a third process equipment including a second optical measuring equipment therein; and a scanning electron microscope, wherein the main controller provides the process conditions to the first process equipment, the second process equipment, the third process equipment, the first measuring equipment, and the second measuring equipment, wherein the main controller is provided the measured data from the first process equipment, the second process equipment, the third process equipment, the first measuring equipment, and the second measuring equipment.

Details of other embodiments are included in this Detailed Description of Exemplary Embodiments section and the drawings.

### BRIEF DESCRIPTION OF THE DRAWINGS

Exemplary embodiments are described in further detail below with reference to the accompanying drawings.

FIG. 1 is a schematic flowchart illustrating a process control method according to an exemplary embodiment of the inventive concept.

FIGS. 2 through 5D are schematic flowcharts of process control methods for processing semiconductor wafers according to various exemplary embodiments of the inventive concept.

FIG. 6 is a block diagram illustrating a process control system according to other exemplary embodiments of the inventive concept.

### DETAILED DESCRIPTION OF EXEMPLARY EMBODIMENTS

Various exemplary embodiments will now be described more fully with reference to the accompanying drawings in which some exemplary embodiments are shown. This inventive concept, however, may be embodied in many alternate forms and should not be construed as limited to only exemplary embodiments set forth herein.

Accordingly, while exemplary embodiments are capable of various modifications and alternative forms, embodiments thereof are shown by way of example in the drawings and will herein be described in detail. It should be understood, however, that there is no intent to limit exemplary embodiments to the particular forms disclosed, but on the contrary, exemplary embodiments are to cover all modifications, equivalents, and alternatives falling within the scope of the inventive concept. Like numbers refer to like elements throughout the description of the figures. It will be understood that when an element is referred to as being “connected” or “coupled” to another element, it can be directly connected or coupled to the other element or intervening elements may be present.

Exemplary embodiments of the inventive concept relate to a semiconductor device and methods of fabricating the same. Other exemplary embodiments of the inventive concept relate to a semiconductor device having a trench isolation region and methods of fabricating the same.

The inventors studied technologies capable of improving the dispersion measurement and/or process control capabilities for fabricating semiconductor devices using existing equipment, and propose improved dispersion measurement and/or process control techniques.

According to an embodiment of the inventive concept, in a process that involves measuring many positions on a semiconductor wafer, optical measuring equipment having a short measuring time is used, and overall measurements and errors are periodically corrected using electron beam or high-resolution measuring equipment. Here, the period or duration of measurement is based on a process period or duration of, for example, one lot of semiconductor wafers, which provides for convenient process management. According to another embodiment of the inventive concept, when a position measured by the optical measuring equipment has an unexpected measured value, i.e. deviates from a tolerance range, additional measurement processes may be made using electron beam or the high-resolution measuring equipment. For example, optical measurement is always performed before and/or after any specified process, and electron beam measurements are periodically performed. To this end, when the optical measuring equipment is mounted on or included in equipment for performing the specified process, it is possible to reduce variability between processes and improve productivity.

Hereinafter, various exemplary embodiments will be described with reference to the accompanying flowcharts.

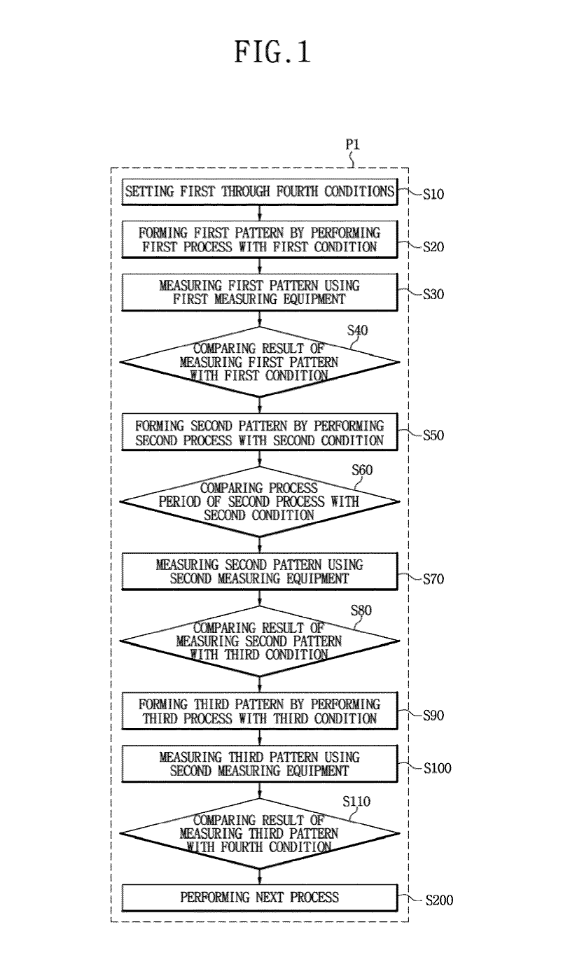

FIG. 1 is a flowchart of a process control method according to an exemplary embodiment of the inventive concept. FIG. 1 will describe an example of applying a technical idea of the inventive concept to an exemplary, non-limiting etching process.

Referring to FIG. 1, a process control method for controlling processing of semiconductor wafers according to an exemplary embodiment includes a first procedure P1. The first procedure P1 includes a first step S10 of setting first through fourth conditions, a second step S20 of forming a first pattern by performing a first process on the semiconductor wafer, a third step S30 of measuring the first pattern using first measuring equipment, a fourth step S40 of comparing a result of measuring the first pattern with the first condition, a fifth step S50 of forming a second pattern by performing a second process on the semiconductor wafer, a sixth step S60 of comparing a period or duration of the second process with the second condition, a seventh step S70 of measuring a second pattern using second measuring equipment, an eighth step S80 of comparing a result of measuring the second pattern with the third condition, a ninth S90 step of forming a third pattern by performing a third process on the semiconductor wafer, a tenth step S100 of measuring the third pattern using the second measuring equipment, and an eleventh step S110 of comparing a result of measuring the third pattern with the fourth condition.

The fifth step S50 of forming the second pattern by performing the second process on the semiconductor wafer may be performed when the result of measuring the first pattern has been shown to satisfy the first condition in the fourth step S40.

The seventh step S70 of measuring the second pattern using the second measuring equipment may be performed regardless of whether or not the second process duration has been shown to satisfy the second condition in the sixth step S60.

The ninth step S90 of forming the third pattern by performing the third process on the semiconductor wafer may be performed when the result of measuring the second pattern has been shown to satisfy the third condition in the eighth step S80.

The final step S200 of performing a next process may proceed when the result of measuring the third pattern has been shown to satisfy the fourth condition in the eleventh step S110. In other words, when the first procedure P1 is completed, the next process may be performed.

The first condition may include information about formation of the first pattern such as a thickness of the first pattern. The first condition may also include refraction indices (n) and permittivity (k) of materials that form the first pattern. In addition, the first condition may also include results of measuring the first pattern using the first measuring equipment. For example, refraction indices and permittivity of each material may be reference variables for calculating the thickness, etc. of the first pattern to determining whether or not the first pattern satisfies the first condition. In other words, by pre-setting the first condition, it is possible to determine whether or not the first pattern is properly or allowably formed. In this exemplary embodiment, the first pattern may be a material layer, particularly a dielectric layer that may be formed on the entire surface of the semiconductor wafer. Since the specific refraction indices and permittivity of each material are well known, the first condition may include the thickness of the first pattern, or the refraction indices or permittivity of the first pattern depending on its thickness.

The second condition may include a maximum duration of the second process or a maximum number of repetitions of the second process. For example, the second condition may include a condition for counting how many times the first procedure P1 is repeated. An initial value of the second condition may be set to 0 (zero), and the number of wafers or lots of wafers may be set to a unit for counting, where one lot of wafers generally consists of 25 wafers. In other words, the maximum value of the second condition may be set to 25, 50, 75, etc. In this exemplary embodiment, it may be assumed that the second condition is set to a numerical value corresponding to one lot of wafers. However, the wafer lot size is not fixed, and may vary in other applications of the technical idea of the inventive concept. The first procedure P1 may be varied depending on whether or not the process duration or the number of repetitions of the second process satisfies the second condition. This will be described in detail in connection with other exemplary embodiments of the inventive concept. If the duration or number of repetitions of the second process satisfies the second condition, the duration or number of repetitions of the second process will be smaller than the maximum duration or number of repetitions of the second process.

The third condition may include at least one of various process variables, such as a line width, thickness, area, shape, etc. of the second pattern. This exemplary embodiment will assume that the third condition is information of the line width of the second pattern. The fourth condition may include at least one of various process variables, such as a line width, thickness, area, shape, etc. of the third pattern. This exemplary embodiment will assume that the fourth condition is information of the line width of the third pattern. The third and/or fourth conditions may also be set to two or more of the various process variables, for instance the line width and thickness, the line width and area, and so on.

The first process may include a process of forming a material layer. For example, the first process may be a deposition process, such as a chemical or physical vapor deposition process of forming a material layer, a diffusion process of forming a diffusion layer, an ion implantation process of foaming an impurity layer, a coating process, a chemical or physical passivation process and/or a plating process. In other words, the first process may be a process of forming a new material layer, or a process of forming a material layer having a chemically special function. In particular, without limitation, for clarity of exposition, the first process may be regarded as a deposition process.

The second process may include a process of forming a mask pattern. For example, the second process may be a process of forming a mask pattern for preventing portions of a target layer from being etched when the target layer is to be patterned using an etching method. An exemplary, non-limiting mask pattern is a photoresist pattern. For clarity of exposition, the following description will assume, without limitation, that the second process is a process of forming the photoresist pattern. If the second process is a process of forming a photoresist pattern, it should be understood that the second process may include a process of forming a photoresist layer, a dry process, a baking process, a lithography process, a development process, and a cleaning process, and so on if necessary. Furthermore, when the mask pattern is a hard mask pattern such as an inorganic material, it should be understood that both a process of forming an inorganic material layer for a hard mask pattern and a process of patterning the inorganic material layer to form the hard mask pattern are included in the second process.

A recipe of the second process may be preset, and corrected with reference to the result of measuring the first pattern. If the result of measuring the first pattern is within a preset tolerance, the second process will be performed according to the preset recipe of the second process. In contrast, if the result of measuring the first pattern is out of the preset tolerance, the recipe of the second process may be corrected with reference to the result of measuring the first pattern. Further, the recipe of the second process may be corrected by feedback from the result of measuring the second pattern.

The second process may include an etching process, namely, a pattering process of forming the third pattern using the second pattern as an etching mask. The third process may include various patterning processes, which will not be described in detail. However, it should be understood that the third process includes all processes of patterning a target layer. This exemplary embodiment will be described assuming, without limitation, that the third process is an etching process, particularly a dry etching process. Further, if the second pattern is a pattern to be removed, for instance a photoresist pattern, the third process may include a process of removing the second pattern. Thus, the process of measuring the third pattern using the second measuring equipment may be performed before and/or after the second pattern is removed. Further, after the third pattern is formed, a cleaning process may be performed. The third pattern may be measured before or after this cleaning process, with a pre-cleaning measurement and/or post-cleaning measurement.

If the second pattern is a photoresist pattern, the third process may include processes of removing the photoresist pattern such as a stripping process and/or a plasma ashing process. Further, the third process may include a cleaning process regardless of whether or not the second pattern is the photoresist pattern as above.

A recipe of the third process may be preset and corrected with reference to the result of measuring the first pattern and/or the result of measuring the second pattern. If the result of measuring the first and/or second patterns is within a preset tolerance, the third process will be performed according to the preset recipe of the third process. In contrast, if the result of measuring the first and/or second patterns is out of the preset tolerance, the recipe of the third process may be corrected with reference to the result of measuring the first and/or second patterns. Otherwise the result of measuring the first pattern and/or the result of measuring the second pattern may be corrected with reference to the comparisons. The corrections may include correcting equipment errors.

The first pattern may be a material layer pattern for a material layer that may be formed on the entire surface of a wafer. In this exemplary embodiment, the first pattern may be a patterning target layer that may be patterned into the third pattern.

The second pattern may be a mask pattern such as a photoresist pattern, i.e. an etching mask pattern. Further, when a hard mask is applied, the second pattern may be a hard mask pattern. Here, the hard mask may be interpreted, without limitation, as a material layer having better etching resistance than a target layer to be patterned.

The third pattern may be formed by patterning the first pattern. For example, the first pattern may be etched into the third pattern using the second pattern as an etching mask. The formation of the third pattern may be interpreted, without limitation, as the removal of the second pattern serving as the photoresist pattern. However, if the second pattern includes a hard mask, the second pattern may remain on the third pattern in part or in whole without being removed. If a part of the second pattern or another material pattern remains on the third pattern, this remaining pattern may be regarded as a part of the third pattern.

The first and second measuring equipment may be optical measuring equipment, i.e. measuring equipment using light. The measuring equipment may be generally classified into optical measuring equipment, and electron beam measuring equipment. The optical measuring equipment has relatively lower resolution than the electron beam measuring equipment. However, the optical measuring equipment is less expensive, uses a simpler measuring process, and has a shorter measuring time, compared to the electron beam measuring equipment. However, the use of preset recipes according to an exemplary embodiment of the inventive concept can compensate for the lower resolution of the optical measuring equipment. For example, each condition may be preset by modeling refraction indices, reflectivity, as well as the geometric topology of the layer materials. In this case, each measured value may be preset in an image or a graph, and the process of measuring each pattern can be performed by comparing the preset values to values measured by the first and second measuring equipment in real time. A measuring method according to an embodiment of the inventive concept can reduce a time required for measurement and comparison and obtain more accurate results within a shorter time. Further, since numerical values to be measured according to modeled conditions are previously input, unforeseeable errors of the measuring equipment may be reduced.

The result of measuring the first pattern using the first measuring equipment may be utilized as reference data for setting process recipes for performing the second and/or third processes.

Measurement of the first pattern using the first measuring equipment may include information about the formation of the first pattern, such as the thickness of the first pattern, i.e. information associated with the first condition.

Measurement of the second pattern using the second measuring equipment may include information about formation of the second pattern, such as the line width of the second pattern, i.e. information associated with the third condition.

Measurement of the third pattern using the second measuring equipment may include information about formation of the third pattern, such as the thickness of the third pattern, i.e. information associated with the fourth condition. In this exemplary embodiment, when the third process includes a cleaning process, measurement of the third pattern using the second measuring equipment may include the process of measuring the third pattern after the cleaning process. In addition, the third pattern may be measured before the cleaning process. In other words, both of the measuring processes may be performed.

A process control method according to an exemplary embodiment may ensure rapid processing since it sets each recipe to control each process using optical measuring equipment, and includes a procedure capable of comparing recipes modeled by the respective recipes with real measured values. In particular, each pattern is measured before or after each process is performed using optical measuring equipment, and thus a process control method according to an embodiment of the inventive concept can obtain accurate information about the patterns and processes.

According to a technical idea of the inventive concept, the first, second and third processes may be performed using respective processing equipment. For example, the first process may be a deposition process and may be performed in deposition process equipment. The second process may be a photolithography process and may be performed in photolithography equipment. The third process may be an etching process and may be performed in etching equipment.

According to a technical idea of the inventive concept, the first measuring equipment may be provided in the equipment for performing the first process. The second measuring equipment may be provided in the equipment for performing the third process. Thus, the first measuring equipment may be included in the equipment for performing the first process, e.g. the deposition equipment. Further, the second measuring equipment may be included in the equipment for performing the third process, e.g. the etching equipment. In particular, when the second measuring equipment is included in the equipment for performing the third process, two measuring processes may be performed by the same equipment, i.e. the equipment for performing the third process.

According to a technical idea of the inventive concept, the process of measuring the second pattern and the process of measuring the third pattern may both be performed using the second measuring equipment, and the second measuring equipment may be included in the equipment for performing the third process.

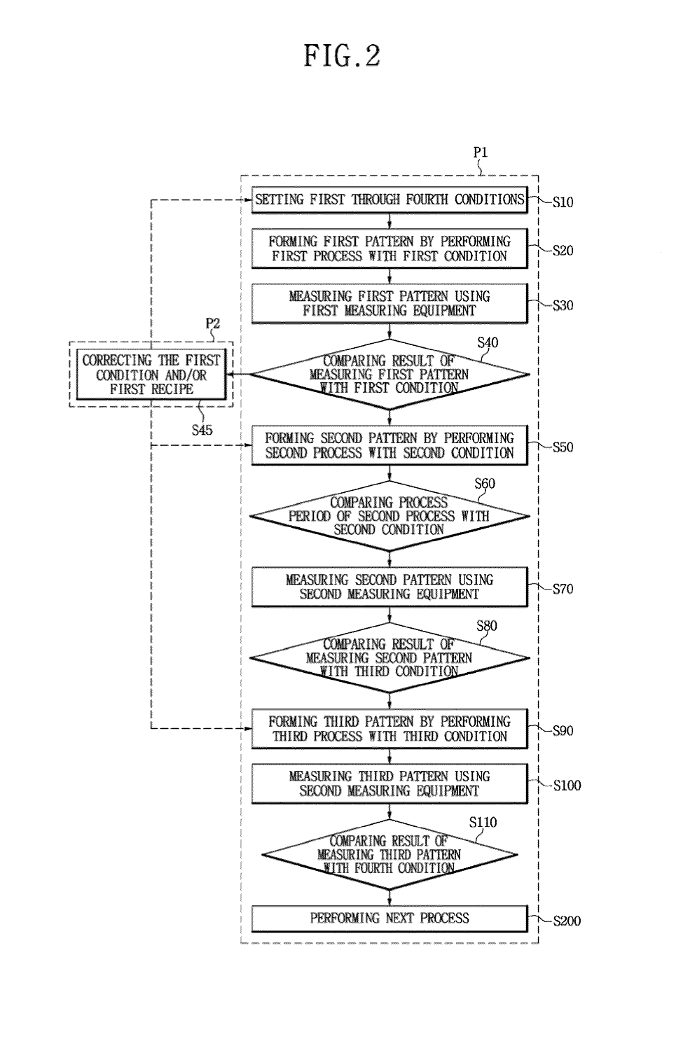

FIG. 2 is a flowchart of a process control method for controlling processing of semiconductor wafers according to another exemplary embodiment of the inventive concept. Referring to FIG. 2, a process control method for controlling processing of semiconductor wafers includes a first procedure P1 and a second procedure P2. The first procedure P1 includes a first step S10 of setting first through fourth conditions, a second step S20 of forming a first pattern by performing a first process on the semiconductor wafer according to a first process recipe, a third step S30 of measuring the first pattern using first measuring equipment, a fourth step S40 of comparing a result of measuring the first pattern with the first condition, a fifth step S50 of forming a second pattern by performing a second process on the semiconductor wafer according to a second process recipe, a sixth step S60 of comparing a duration of the second process with the second condition, a seventh step S70 of measuring a second pattern using second measuring equipment, an eight step S80 of comparing a result of measuring the second pattern with the third condition, a ninth step S90 of forming a third pattern by performing a third process on the semiconductor wafer according to a third process recipe, a tenth step S100 of measuring the third pattern using the second measuring equipment, and an eleventh step S110 of comparing a result of measuring the third pattern with the fourth condition. The second procedure P2 includes a step S45 of correcting the first condition and/or first recipe when the result of measuring the first pattern does not satisfy the first condition in the fourth step S40 of the first procedure P1.

In the second procedure P2, when the result of measuring the first pattern using the first measuring equipment does not satisfy the first condition, it may be utilized as reference data for correcting the first condition, the second and/or third process recipes. Further, the second procedure P2 may include the step S45 of transmitting a result of correcting the first condition back to the step of setting the first condition. In the figures, these functions are depicted by a dotted line. Moreover, the step S45 may include correcting recipes of the second and/or third process. Otherwise the result of measuring the first pattern may be corrected with reference to the comparison. The corrections may also correct equipment errors.

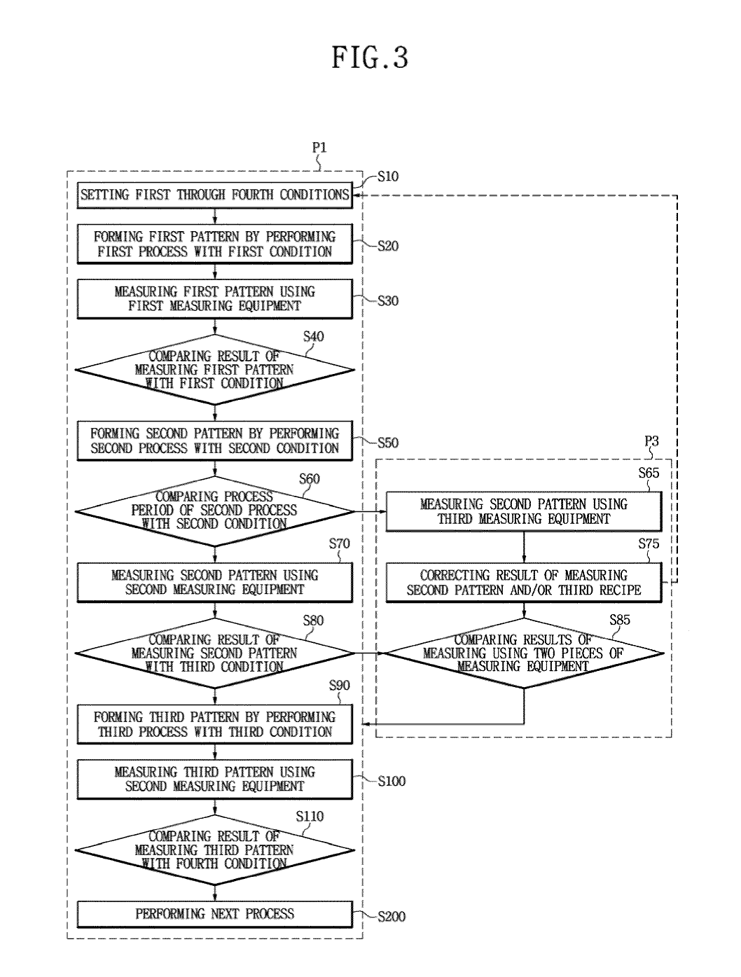

FIG. 3 is a flowchart of a process control method for controlling processing of semiconductor wafers according to another exemplary embodiment of the inventive concept. Referring to FIG. 3, a process control method for processing semiconductor wafers includes a first procedure P1 and a third procedure P3. The first procedure P1 includes a first step S10 of setting first through fourth conditions, a second step S20 of forming a first pattern by performing a first process on the semiconductor wafer, a third step S30 of measuring the first pattern using first measuring equipment, a fourth step S40 of comparing a result of measuring the first pattern with the first condition, a fifth step S50 of forming a second pattern by performing a second process on the semiconductor wafer when the result of measuring the first pattern is spec-in of the first condition, a sixth step S60 of comparing a duration of the second process with the second condition, a seventh step S70 of measuring a second pattern using second measuring equipment when the second process duration satisfies the second recipe, an eighth step S80 of comparing a result of measuring the second pattern with the third condition, a ninth step S90 of forming a third pattern by performing a third process on the semiconductor wafer when the result of measuring the second pattern satisfies the third condition, a tenth step S100 of measuring the third pattern using the second measuring equipment, an eleventh step S110 of comparing a result of measuring the third pattern with the fourth condition, and final step S200 of performing a next process when the result of measuring the third pattern satisfies the fourth condition. The third procedure P3 includes a first step S65 of measuring the second pattern using third measuring equipment when the second process duration or the number of repetitions does not satisfy the second condition in the sixth step S60, and a second step S75 of correcting the result of measuring the second pattern using the third measuring equipment with reference to the comparison results.

The fifth step S50 of forming the second pattern by performing the second process on the semiconductor wafer may proceed when the result of measuring the first pattern using the first measuring equipment satisfy the first condition in the fourth step S40.

The seventh step S70 of measuring the second pattern using the second measuring equipment may proceed regardless of whether or not the second process duration satisfies the second condition in the seventh step S70.

The ninth step S90 of forming the third pattern by performing the third process on the semiconductor wafer may proceed when the result of measuring the second pattern using the second measuring equipment satisfies the third condition in the eighth step S80.

The second procedure P3 may further include a third step S85 of comparing the result of measuring the second pattern using the third measuring equipment with the result of measuring and correcting the second pattern using the second measuring equipment when the result of measuring the second pattern using the second measuring equipment satisfies the third condition in the eighth step S80. On the basis of the result of the comparison, the recipe of the third process may be corrected. In other words, the third process may proceed on the basis of the corrected recipe. Otherwise, the first process equipment, the second process equipment, the first measuring equipment, and the second measuring equipment may be corrected for mechanical errors thereof.

The final step S200 of performing the next process may proceed when the result of measuring the third pattern satisfies the fourth condition in the eleventh step S110. In other words, when the first procedure P1 is completed, the next process may be performed.

The third measuring equipment may use an electron beam, and in particular may be a scanning electron microscope (SEM), and more particularly an in-line SEM. Since an SEM may be used for various measuring purposes, it is typically operated either in a individual measuring room which is prepared aside from a producing line or in a separate room within the producing line. The in-line SEM is specialized for measuring patterns, particularly a line width of, for instance, a line or a contact, and is installed and operated within the producing line. The in-line SEM has the same fundamental measuring principle as the SEM. The in-line SEM has better resolution than the optical measuring equipment, but requires a longer measurement time compared to the optical measuring equipment, and there is a possibility of a pattern size varying due to the charged electrons.

Thus, the result of measuring the second pattern using the third measuring equipment may be corrected with reference to a variable database based on the time required as well as measurement factors or parameters, such as voltage, current, a quantity of electric charge, etc. In detail, when the third measuring equipment is an in-line SEM, the result of measuring the second pattern itself may show a difference compared to other measurements. Thus, the third procedure P3 may further include another step of correcting the result of measuring the second pattern using the third measuring equipment.

As set forth above, even when the duration or number of repetitions of the second process fails to satisfy the second condition, the second pattern may be measured using the second measuring equipment. As a result, when a result of measuring the second pattern using the second measuring equipment satisfies the third condition, the third process may be performed under the set recipe.

The third procedure P3 may include a process of feeding the results of the measurement and correction back to the first step S10 for re-setting the second and third conditions.

Each pattern measured by the third measuring equipment may be identical to that measured by the second measuring equipment.

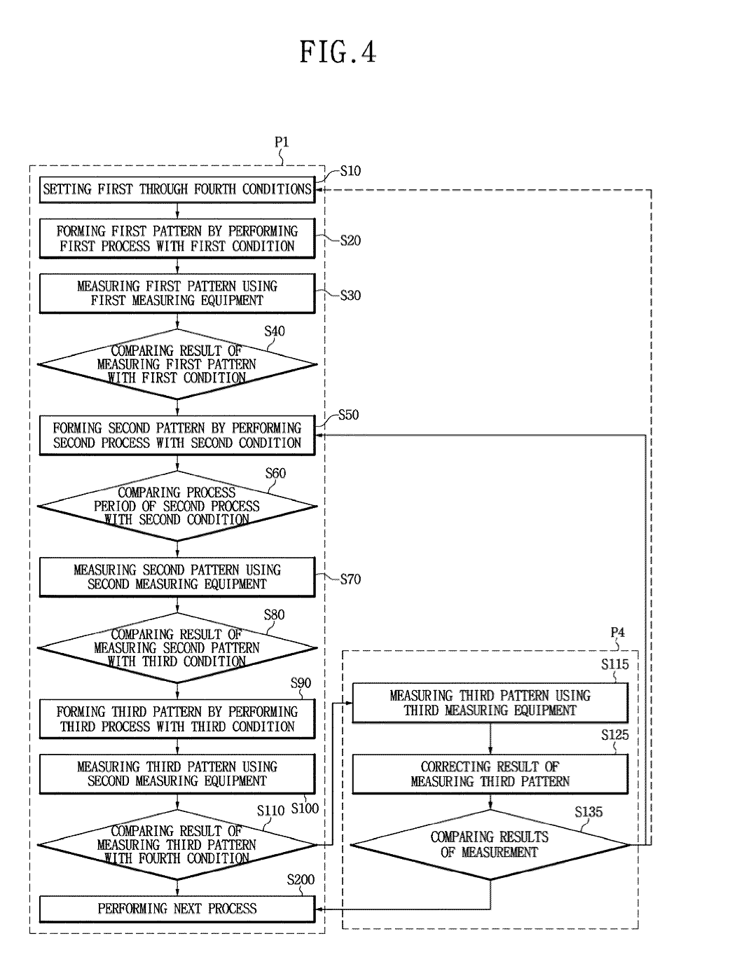

FIG. 4 is a flowchart of a process control method for controlling processing of semiconductor wafers according to another exemplary embodiment of the inventive concept. Referring to FIG. 4, a process control method for processing semiconductor wafers includes a first procedure P1 and a fourth procedure P4. The first procedure P1 includes a first step S10 of setting first through fourth conditions, a second step S20 of forming a first pattern by performing a first process on the semiconductor wafer, a third step S30 of measuring the first pattern using first measuring equipment, a fourth step S40 of comparing a result of measuring the first pattern with the first condition, a fifth step S50 of forming a second pattern by performing a second process on the semiconductor wafer when the result of measuring the first pattern satisfies the first condition, a sixth step S60 of comparing a second process duration with the second condition, a seventh step S70 of measuring a second pattern using second measuring equipment when the second process duration satisfies the second condition, an eighth step S80 of comparing a result of measuring the second pattern with the third condition, a ninth step S90 of forming a third pattern by performing a third process on the semiconductor wafer when the result of measuring the second pattern satisfies the third condition, a tenth step S100 of measuring the third pattern using the second measuring equipment, an eleventh step S110 of comparing a result of measuring the third pattern with the fourth condition, and a final step S200 of performing a next process when the result of measuring the third pattern satisfies the fourth condition. The fourth procedure P4 includes a first step S115 of measuring the third pattern using third measuring equipment when the result of measuring the third pattern using the second measuring equipment in the eleventh step S110 do not satisfy the fourth condition, a second step S125 of correcting the result of measuring the third pattern, and a third step S135 of comparing a correction of the result of measuring the third pattern with the result of measuring the third pattern using the second measuring equipment.

The fourth procedure P4 may be performed when the result of measuring the third pattern using the second measuring equipment does not satisfy the fourth condition in the fourth comparing step S110.

The fourth procedure P4 may include either a process of transmitting to the next process the result of step 135, or a process of transmitting the result of step 135 to the fifth step S50 for correcting the recipe of the second process, or a process of transmitting the result of step 135 to the first step S10 for re-setting the fourth condition.

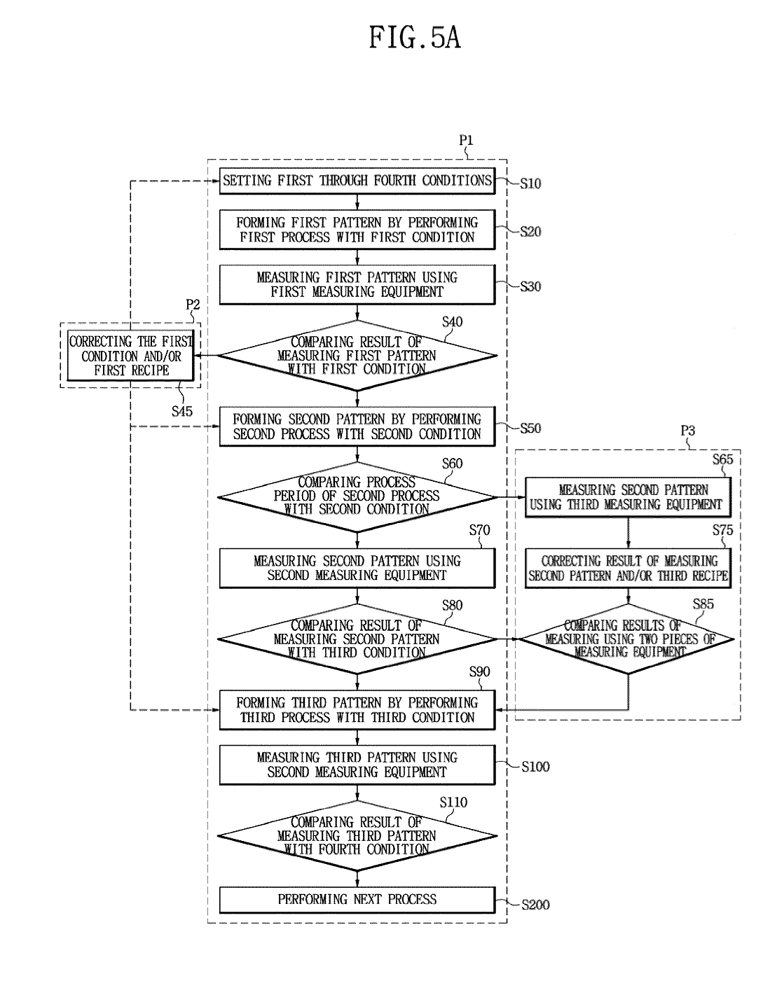

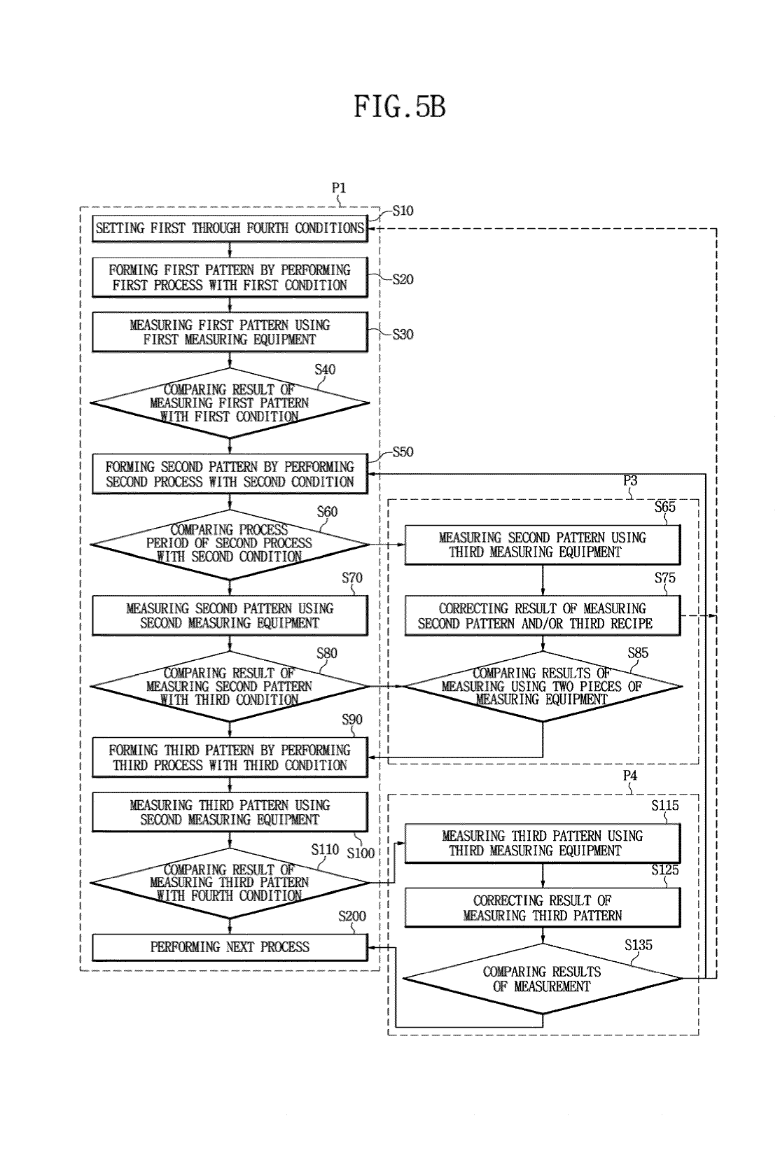

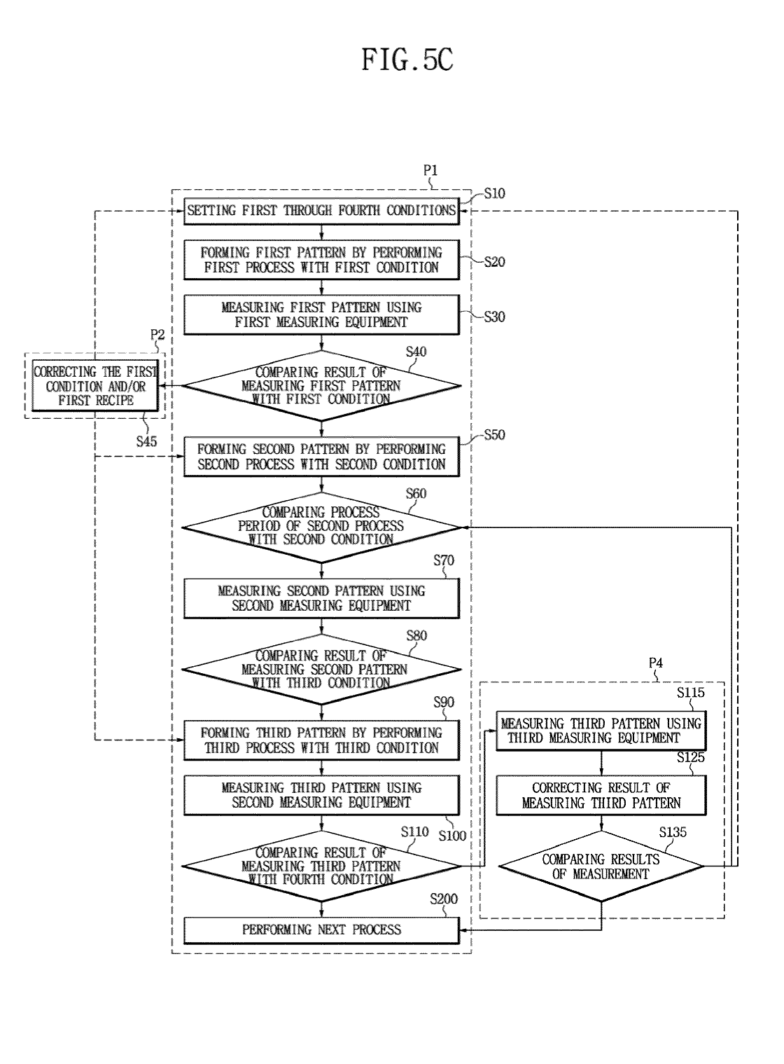

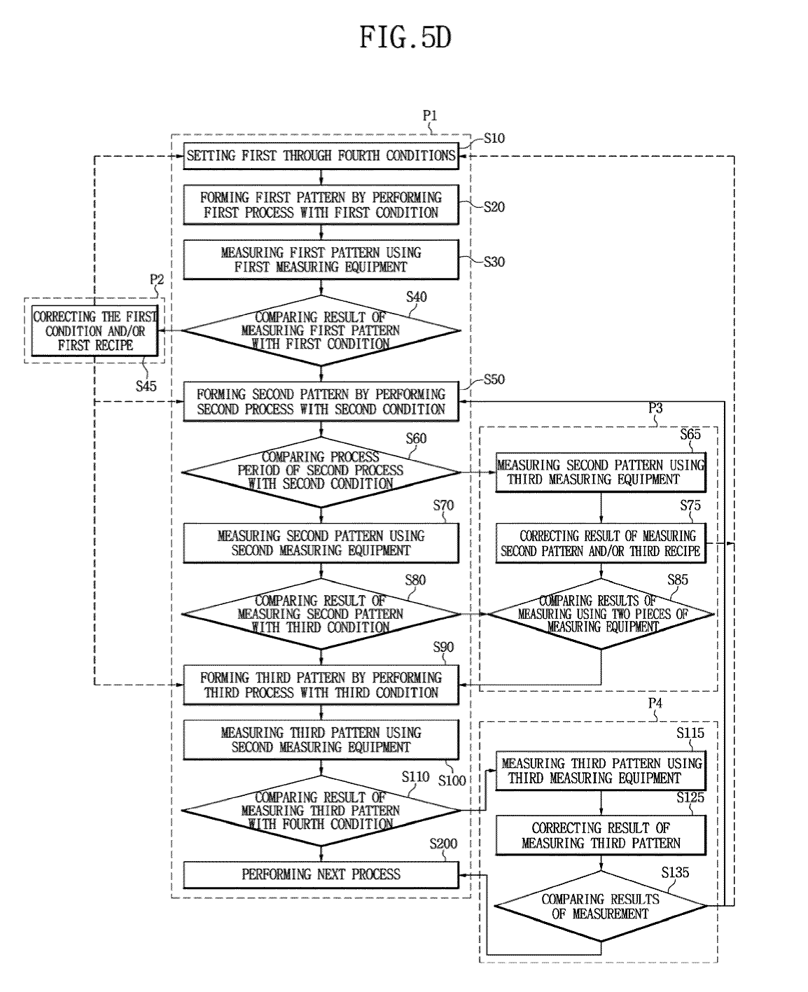

The various exemplary embodiments of the inventive concept need not be independent of each other. In other words, the exemplary embodiments of FIGS. 1-4 may be combined with each other. Examples of such combinations are illustrated in FIGS. 5A through 5D.

FIGS. 5A through 5D illustrate combinations of process control methods according to other exemplary embodiments of the inventive concept. Referring to FIG. 5A, a process control method for processing semiconductor wafers according to another exemplary embodiment includes the first procedure P1, the second procedure P2, and the third procedure P3.

Referring to FIG. 5B, a process control method for controlling a process of processing semiconductor wafers according to another exemplary embodiment includes the first procedure P1, the third procedure P3, and the fourth procedure P4.

Referring to FIG. 5C, a process control method for controlling a process of processing semiconductor wafers according to another exemplary embodiment includes the first procedure P1, the second procedure P2, and the fourth procedure P4.

Referring to FIG. 5D, a process control method for controlling a process of processing semiconductor wafers according to another exemplary embodiment includes the first procedure P1, the second procedure P2, the third procedure P3, and the fourth procedure P4.

All of the procedures have been described, and their combinations will be fully understood from the description above.

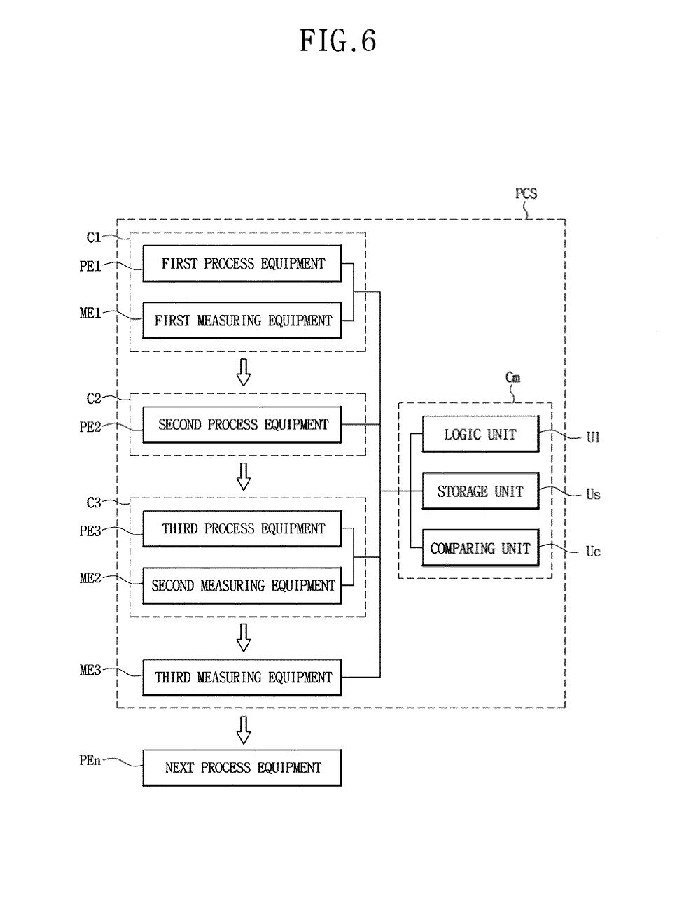

FIG. 6 is a block diagram illustrating a process control system PCS according to exemplary embodiments of the inventive concept. Referring to FIG. 6, the process control system PCS may include a main cluster Cm, a first cluster C1, a second cluster C2, a third cluster C3, and a scanning microscope ME3.

The main cluster Cm may include a logic unit U1 to set process conditions and/or control the first to third clusters and a storage unit Us to store the conditions and measured data transmitted from the clusters. The main cluster Cm may further include a comparing unit Uc to compare the process conditions with the measured data transmitted from the clusters. The logic unit U1 may further command the clusters to correct recipes based on the results of the comparison of the process conditions and the measured data.

The first cluster C1 may include first process equipment PE1 and first measuring equipment ME1. The second cluster C2 may include second process equipment PE2. The third cluster C3 may include third process equipment PE3 and second measuring equipment ME2.

The first cluster C1 may be the first process equipment PE1 including the first measuring equipment ME1 therein. The second cluster C2 may be the second process equipment PE1. The third cluster C3 may be the third process equipment PE3 including the second measuring equipment ME2 therein. Otherwise, the first process equipment PE1 and/or the third process equipment PE3 may include optical measuring functions.

The solid lines may indicate signal communication lines to transmit signals for commands and data. The dotted lines (or rectangles) may indicate clusters. The arrows may indicate wafer flows.

The main cluster Cm may control the first cluster C1, the second cluster C2, and the third cluster C3. For example, the main cluster Cm may provide process conditions and/or recipes associated with most or all of the processes. Furthermore, the main cluster Cm may store the conditions and/or recipes. The main cluster Cm may include a microprocessor. The microprocessor may be included in the logic unit U1.

The first process equipment PE1 may form a first pattern by performing a first process on the semiconductor wafer. For example, the first process may be a deposition process, thus the first process equipment PE1 may be deposition equipment.

The first measuring equipment ME1 may measure the first pattern using light and generate information about the first pattern such as pattern width, pattern thickness and so on. The generated information about the first pattern in the first measuring equipment ME1 may be provided to the main cluster Cm. The main cluster Cm may control the other clusters based on the information about the first pattern. Further, the first measuring equipment ME1 may be included in the first process equipment. Thus, a first cluster C1 may include the first process equipment and the first measuring equipment. Otherwise, the first process equipment PE1 may include an optical measuring function for measuring the first pattern. In this case, the first cluster C1 may be the first process equipment PE1 including a measuring function.

The second process equipment PE2 may form a second pattern. The second pattern may be formed on the first pattern. The second pattern may be a mask pattern to mask the first pattern from an etch process. For example, the second process equipment PE2 may be photolithography equipment. When the second process equipment PE2 is photolithography equipment, the second cluster C2 may include a photoresist film coater, a bake oven, an irradiator, a developer, etc. Thus, the second cluster C2 may be a second process equipment PE2 including at least one of the photoresist film coater, the bake oven, the light irradiator (a stepper or a scanner), the developer, etc. Otherwise the second process equipment PE2 may include at least one of photoresist coating function, photoresist baking function, irradiating function, developing function, etc.

The third process equipment PE3 may form a third pattern by performing a third process on the semiconductor wafer. For example, the third process may be a patterning process, thus the third pattern may be formed by pattering the first pattern using the patterning process and second pattern as a patterning mask. The third process equipment PE3 may be patterning equipment such as etching equipment. The third process may further include a mask pattern removing function. Thus, the third process equipment PE3 may include removing equipment to remove, strip or ash the second pattern such as a photoresist pattern.

The second measuring equipment ME2 may measure the second pattern and/or the third pattern using light and generate information about the second pattern and/or the third pattern, such as pattern widths, pattern thicknesses and so on, respectively. The generated information about the first pattern and/or the third pattern in the second measuring equipment ME2 may be provided to the main cluster Cm, respectively. The main cluster Cm may control the other clusters based on the information about the second pattern and the third pattern, respectively. Further, the second measuring equipment ME2 may be included in the third process equipment PE3. Thus, a third cluster C3 may include the third process equipment PE3 and the second measuring equipment ME2. Otherwise, the third process equipment PE3 may include an optical measuring function for measuring the second pattern and/or the third pattern. In this case, the third cluster may be the third process equipment PE3 including the measuring functions.

The third measuring equipment ME3 may be a scanning electron microscope (SEM). The third measuring equipment ME3 may measure the third pattern. The third measuring equipment ME3 may transmit measured data to the main cluster Cm.

The next process equipment PEn may be any equipment for processing the third pattern therein such as cleaning equipment, surface treatment equipment, deposition equipment, plating equipment, and etc.

Detailed operating description of the process control system PCS may be interpreted based on the above described specification.

The technical idea of the inventive concept provide methods and systems of efficiently controlling processes for measuring patterns in any advanced process technology, in particular measuring dispersion of the patterns.

As set forth above, process control system and method according to embodiments of the inventive concept can stably control processes while efficiently using the measuring equipment, to increase semiconductor productivity and maintain a high yield.

The foregoing is illustrative of exemplary embodiments and is not to be construed as limiting thereof. Although a few exemplary embodiments have been described, those skilled in the art will readily appreciate that many modifications are possible in exemplary embodiments without materially departing from the novel teachings. Accordingly, all such modifications are intended to be included within the scope of this inventive concept as defined in the claims. Therefore, it is to be understood that the foregoing is illustrative of various exemplary embodiments and is not to be construed as limited to the specific embodiments disclosed, and that modifications to the disclosed embodiments, as well as other embodiments, are intended to be included within the scope of the appended claims.

What is claimed is:

1. A process control method, comprising:
setting first, second, third, and fourth conditions,
forming a first pattern by performing a first process on a semiconductor wafer,
measuring the first pattern using a first measuring equipment to obtain a first result,
comparing said first result with the first condition,
forming a second pattern by performing a second process on the semiconductor wafer,
comparing a period of the second process with the second condition,
measuring the second pattern using a second measuring equipment to obtain a second result,
comparing said second result with the third condition,
forming a third pattern performing a third process on the semiconductor wafer,
measuring the third pattern using the second measuring equipment to obtain a third result, and
comparing said third result with the fourth condition.

2. The process control method according to claim 1, wherein the first condition includes information associated with at least one of a thickness, refraction index, and permittivity of the first pattern.

3. The process control method according to claim 1, wherein the second condition includes maximum duration of the second process or a maximum number of repetitions of the second process.

4. The process control method according to claim 1, wherein the third condition includes information associated with at least one of a line width, a thickness, an area, and a shape of the second pattern, and the fourth condition includes information associated with at least one of a line width, a thickness, an area, and a shape of the third pattern.

5. The process control method according to claim 1, wherein the first pattern includes a material layer formed on the semiconductor wafer, the second pattern includes a mask pattern formed on the material layer, and the third pattern includes a material layer pattern that is patterned using the mask pattern as a patterning mask.

6. The process control method according to claim 1, wherein the first process is a process of forming a material layer on the semiconductor wafer, the second process is a process of forming a mask pattern on the material layer, and the third process is a process of patterning the material layer using the mask pattern as a patterning mask.

7. The process control method according to claim 1, wherein measuring the first pattern using the first measuring equipment includes measuring a characteristic of the first pattern corresponding to the first condition.

8. The process control method according to claim 1, wherein measuring the second pattern using the second measuring equipment includes measuring a characteristic of the second pattern corresponding to the third condition.

9. The process control method according to claim 1, further comprising measuring the second pattern using third measuring equipment to obtain a fourth result, after comparing the period of the second process with the second condition.

10. The process control method according to claim 9, further comprising correcting the fourth result, and comparing the corrected fourth result with the second result.

11. The process control method according to claim 1, further comprising correcting the first condition based on said first result.

12. The process control method according to claim 1, wherein measuring the third pattern using the second measuring equipment includes measuring a characteristic of the third pattern corresponding to the fourth condition.

13. The process control method according to claim 1, further comprising measuring the third pattern using third measuring equipment to obtain a fifth result, after comparing the third result with the fourth condition.

14. The process control method according to claim 13, further comprising correcting the fifth result in consideration of a measurement error of the third measuring equipment.

15. The process control method according to claim 14, further comprising comparing the corrected fifth result with the third result.

16. The process control method according to claim 1, wherein the first process is performed in first process equipment; the second process is performed in second process equipment; and the third process is performed in third process equipment,
wherein the first, second and third process equipment differ from each other, and the second measuring equipment is included in the third process equipment.

17. A method of controlling a process of fabricating a semiconductor device, comprising:
setting first, second, third, and fourth conditions,
processing a semiconductor wafer to form a material layer on the surface of the wafer;
measuring the first pattern using a first measuring equipment to obtain a first result;
comparing said first result with a first condition;
correcting the first condition based on said first result;
processing the semiconductor wafer to form a mask pattern on the material layer;
measuring the mask pattern using a second measuring equipment to obtain a second result;
comparing said second result with a third condition,
measuring the mask pattern using third measuring equipment to obtain a fourth result;
correcting the fourth result, and comparing the corrected fourth result with the second result; and
processing the semiconductor wafer to form a material layer pattern using the mask pattern as a patterning mask.

18. The method of claim 17, further comprising measuring a period of the process of forming said mask pattern, wherein mask pattern is measured using said third measuring equipment when said period does not satisfy a second condition.

19. The method of claim 17, further comprising measuring the material layer pattern using the second measuring equipment to obtain a third result, and comparing said third result with a fourth condition.

20. A process control method, comprising:
setting first, second, third, and fourth conditions, wherein the first condition includes thickness information, the second condition includes a period information, the third condition includes size information, and the fourth condition includes size information,
forming a material layer by performing a deposition process on a semiconductor wafer,
measuring thickness of the material layer using a first optical measuring equipment to obtain a first result including thickness information of the material layer,
comparing said first result with the first condition,
forming a mask pattern by performing a photolithography process on the semiconductor wafer,
comparing a period of the photolithography process with the second condition,
measuring the mask pattern using a second optical measuring equipment to obtain a second result including sizes information of the mask pattern,
comparing said second result with the third condition,
forming a third pattern performing a patterning process, the patterning process patterning the material layer using the mask pattern as a patterning mask,
measuring the third pattern using the second optic measuring equipment to obtain a third result, and
comparing the third result with the fourth condition,
when the period of the photolithography process does not satisfy the second condition, measuring the mask pattern using an electron beam measuring equipment to obtain a fourth result and comparing the fourth result with the second result, and correcting the third condition based on the fourth result, and
when the third result does not satisfy the fourth condition, measuring the third pattern using the electron beam measuring equipment to obtain a fifth result, and correcting the fourth condition based on the fifth result.
